(19) United States
(12) Patent Application Publication
(10) Pub. No.: US 2025/0191954 A1
(43) Pub. Date: Jun. 12, 2025

(54) CERAMIC SUSCEPTOR

(71) Applicant: NGK INSULATORS, LTD., Nagoya-City (JP)

(72) Inventors: Yutaka UNNO, Handa-Shi (JP); Hajime TAKAHARA, Hashima-Gun (JP)

(73) Assignee: NGK INSULATORS, LTD., Nagoya-City (JP)

(21) Appl. No.: 18/892,686

(22) Filed: Sep. 23, 2024

Related U.S. Application Data
(63) Continuation of application No. PCT/JP2023/044428, filed on Dec. 12, 2023.

(51) Int. Cl. H01L 21/683

(52) U.S. Cl. CPC H01L 21/6833

(57) ABSTRACT

There is provided a ceramic susceptor including: a ceramic plate having a first surface and a second surface and having an RF electrode and a heater electrode embedded therein; a cylindrical ceramic shaft attached to the second surface and having an internal space; an RF rod having one end connected to the RF electrode and having another end extending from the second surface; and a heater rod having one end connected to the heater electrode and having another end extending from the second surface and extending through the internal space. The RF rod includes: a root portion including an end portion to be fitted into a terminal hole formed in the second surface of the ceramic plate; a core portion extending from the root portion in a direction away from the second surface; and a non-magnetic material-made outer circumferential portion covering an outer circumference of the core portion.

### CROSS-REFERENCE TO RELATED APPLICATION

This application is a continuation application of PCT/JP2023/044428 filed Dec. 12, 2023, the entire contents of which are incorporated herein by reference.

### BACKGROUND OF THE INVENTION

### 1. Field of the Invention

The present disclosure relates to a ceramic susceptor.

### 2. Description of the Related Art

In film deposition apparatuses and etching apparatuses for semiconductor manufacturing processes, susceptors are used to support wafers. As such susceptors, susceptors are widely used, each of which includes a ceramic plate for a wafer being placed, and a cylindrical ceramic shaft attached to the ceramic plate. The ceramic plate generally has a configuration in which internal electrodes such as a heater electrode, an RF electrode, and an electrostatic chuck (ESC) electrode are embedded inside a ceramic base made of aluminum nitride (AlN) or the like, which has excellent heat resistance and corrosion resistance.

In plasma CVD processes, ceramic susceptors are used, each of which includes a ceramic plate in which an RF electrode and a heater electrode are embedded. FIGS. 12 and 13 show schematic examples of conventional film deposition apparatuses 100 and 100′ each including such a ceramic susceptor 110. The film deposition apparatuses 100 and 100′ each include a ceramic plate 112 in which an RF electrode 114 and a heater electrode 116 are embedded, and a plasma upper electrode 104, in a chamber 102. A wafer W is placed on the ceramic plate 112, while a ceramic shaft 118 is provided on the bottom surface of the ceramic plate 112. In the film deposition apparatus 100 shown in FIG. 12, the plasma upper electrode 104 is connected to an RF power source 106, while the RF electrode 114 is connected to the ground 108 via an RF rod 120. In this configuration, RF is applied from the plasma upper electrode 104 to generate plasma as represented by arrows in FIG. 12, and the RF current flows to the ground 108 through the RF rod 120. In the film deposition apparatus 100′ shown in FIG. 13, the plasma upper electrode 104 is connected to the ground 108, while the RF electrode 114 is connected to the RF power source 106 via the RF rod 120. In this configuration, as represented by arrows in FIG. 13, RF is applied from the RF electrode 114 to generate plasma, and RF current flows through the RF rod 120 and flows from the RF electrode 114 to the plasma upper electrode 104.

Various configurations of RF rods have been proposed for ceramic susceptors including such RF electrodes and heater electrodes.

Patent Literature 1 (JP7129587B) discloses a wafer support table including a ceramic base in which an RF electrode and a heater electrode are embedded, a hole provided from one side of the ceramic base toward the RF electrode, and an RF rod joined to the RF electrode exposed at the bottom surface of the hole. This RF rod is a hybrid rod composed of: a first rod member, made of Ni, that forms a region of the RF rod from the head end to a predetermined position (between the head end and the base end); and a second rod member, made of a non-magnetic material such as tungsten, that forms a region of the RF rod from the predetermined position to the base end.

Patent Literature 2 (JP6586259B) discloses a wafer support table including: a ceramic base in which an RF electrode and a heater electrode are embedded; a hole provided from one side of the ceramic base toward the RF electrode; a rod, made of Ni or Kovar®, that is joined to the RF electrode exposed at the bottom surface of the hole; and a thin film of an element of the copper group provided on a predetermined region of the outer circumferential surface of the rod. The thin film of an element of the copper group is provided on the outer circumferential surface of the rod in a region from the base end portion of the rod to a predetermined position that is not inserted into the hole. Specifically, this literature discloses an RF terminal in which a thin Au film (Au plating) is provided on part of the outer circumferential surface of a rod made of Ni.

### CITATION LIST

### Patent Literature

Patent Literature 1: JP7129587B
Patent Literature 2: JP6586259B

### SUMMARY OF THE INVENTION

In recent years, the RF current has increased with the increase in RF power required for plasma CVD. For example, RF current has changed increasingly to higher frequencies, from 13.56 MHz to 27.12 MHz and then to 40 MHz. In addition, due to the skin effect which becomes more pronounced as the frequency increases, the impedance of the RF rod continues to increase. Furthermore, the applied plasma power has increased to 1 KW and even 3 KW in recent years, and the RF rod generates heat due to the RF current, causing worsening of the process results and deterioration of the connection parts (melting, burning, degeneration, etc.) to grow apparent. Therefore, it is conceivable to reduce the impedance of the RF rod in order to reduce the heat generation due to the RF current. However, it has been found that employing an existing configuration for achieving low impedance of the RF rod generates various disadvantages.

The inventors have now discovered that by employing an RF rod including a root portion and a core portion as well as an outer circumferential portion, made of a non-magnetic material, that covers the outer circumference of the core portion, it is possible to provide a ceramic susceptor that can desirably achieve low impedance of the RF rod for preventing increase in heat generation accompanying higher frequencies.

Therefore, an object of the present invention is to provide a ceramic susceptor that can desirably achieve low impedance of an RF rod to prevent increase in heat generation accompanying higher frequencies.

The present disclosure provides the following aspects.

### [Aspect 1]

A ceramic susceptor comprising:
a disk-shaped ceramic plate having a first surface and a second surface, the ceramic plate having an RF electrode and a heater electrode embedded in the ceramic plate;
a cylindrical ceramic shaft attached to the second surface of the ceramic plate, the ceramic shaft having an internal space;
an RF rod having one end connected directly or indirectly to the RF electrode, the RF rod having another end extending from the second surface and extending through the internal space; and
a heater rod having one end connected directly or indirectly to the heater electrode, the heater rod having another end extending from the second surface and extending through the internal space,
wherein the RF rod includes:
   a root portion including an end portion to be fitted into a terminal hole formed in the second surface of the ceramic plate;
   a core portion extending from the root portion in a direction away from the second surface; and
   an outer circumferential portion covering an outer circumference of the core portion, the outer circumferential portion being made of a non-magnetic material.

### [Aspect 2]

The ceramic susceptor according to aspect 1, wherein the non-magnetic material composing the outer circumferential portion comprises at least one selected from the group consisting of brass, titanium, stainless steel, chromium, tungsten, molybdenum, and gold.

### [Aspect 3]

The ceramic susceptor according to aspect 1 or 2, wherein a surface of the outer circumferential portion is plated with gold and/or chromium.

### [Aspect 4]

The ceramic susceptor according to any one of aspects 1 to 3, wherein the outer circumferential portion includes:
a cylindrical portion composed of a tubular member and/or a mesh member formed into a cylindrical shape; and
a cap portion that closes an end portion of the cylindrical portion, the end portion being on an opposite side of the root portion.

### [Aspect 5]

The ceramic susceptor according to any one of aspects 1 to 4, wherein the core portion and the root portion comprises nickel or titanium.

### [Aspect 6]

The ceramic susceptor according to any one of aspects 1 to 5, wherein the core portion includes a rod-shaped member, a cable-shaped member, or a combination thereof.

### [Aspect 7]

The ceramic susceptor according to any one of aspects 1 to 6, wherein the core portion includes:
a first rod-shaped member composing a portion of the core portion on a side of the root portion;
a second rod-shaped member composing a head end portion of the core portion on an opposite side of the root portion; and
a cable-shaped member interposed between the first rod-shaped member and the second rod-shaped member.

### [Aspect 8]

The ceramic susceptor according to any one of aspects 1 to 6, wherein the core portion is composed of a single rod-shaped member.

### [Aspect 9]

The ceramic susceptor according to any one of aspects 1 to 8, wherein the ceramic susceptor includes a plurality of the RF rods; and the plurality of the RF rods are connected in the internal space by a connecting member made of a non-magnetic material in at least one form selected from the group consisting of a mesh, a foil, and a plate.

### [Aspect 10]

The ceramic susceptor according to aspect 9, wherein the non-magnetic material composing the connecting member contains at least one selected from the group consisting of brass, titanium, stainless steel, chromium, tungsten, and molybdenum.

### [Aspect 11]

The ceramic susceptor according to any one of aspects 1 to 10, wherein the RF electrode also functions as an ESC electrode.

### BRIEF DESCRIPTION OF THE DRAWINGS

FIG. 1 is a schematic top view showing an example of a ceramic susceptor according to the present disclosure.

FIG. 2 is a schematic cross-sectional view showing a cross section of the ceramic susceptor shown in FIG. 1 taken along a line 2-2 in an orientation in use.

FIG. 3 is a schematic cross-sectional view showing a cross section of the ceramic susceptor shown in FIG. 1 taken along the line 2-2 in an orientation in manufacture.

FIG. 4 is a schematic cross-sectional view of an RF rod shown in FIGS. 1 to 3.

FIG. 5 is a schematic cross-sectional view showing another example of the ceramic susceptor of the present disclosure.

FIG. 6 is a schematic cross-sectional view of an RF rod shown in FIG. 5.

FIG. 7 is a schematic plan view showing another example of the ceramic susceptor of the present disclosure.

FIG. 8 is a schematic cross-sectional view of RF rods and a connecting member shown in FIG. 7.

FIG. 9 is a schematic top view of the RF rods and the connecting member shown in FIGS. 7 and 8.

FIG. 10 is a schematic cross-sectional view of an RF rod in another example of the ceramic susceptor of the present disclosure.

FIG. 11 is a schematic cross-sectional view showing an example of a terminal connection structure in the ceramic susceptor of the present disclosure.

FIG. 12 is a schematic cross-sectional view showing an example of a conventional film deposition apparatus.

FIG. 13 is a schematic cross-sectional view showing another example of a conventional film deposition apparatus.

### DETAILED DESCRIPTION OF THE INVENTION

A ceramic susceptor according to the present invention is a table, made of ceramic, for supporting a wafer in a semiconductor manufacturing apparatus. Preferably, the ceramic susceptor according to the present invention is a ceramic heater for a semiconductor film deposition apparatus. Typical examples of film deposition apparatuses include CVD (chemical vapor deposition) apparatuses (e.g., thermal CVD apparatuses, plasma CVD apparatuses, photo CVD apparatuses, and MOCVD apparatuses), and PVD (physical vapor deposition) apparatuses, and plasma CVD apparatuses is particularly preferred.

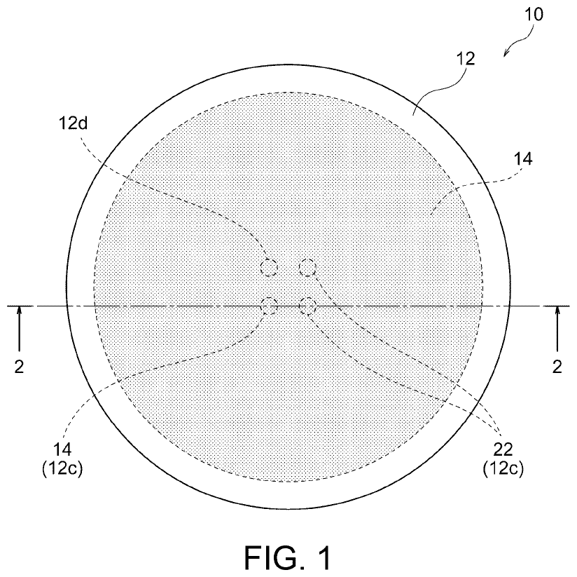

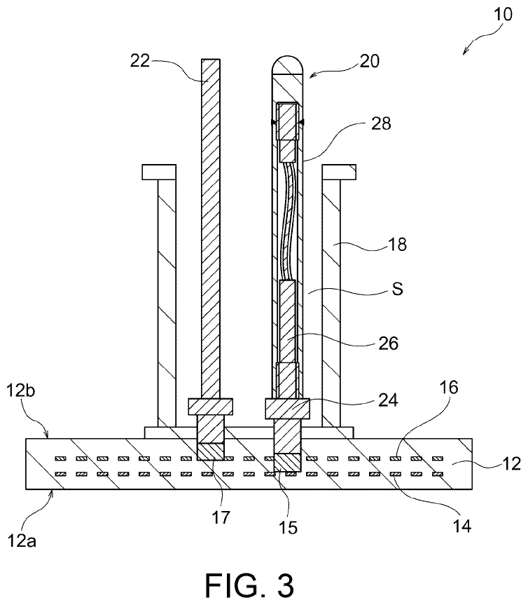

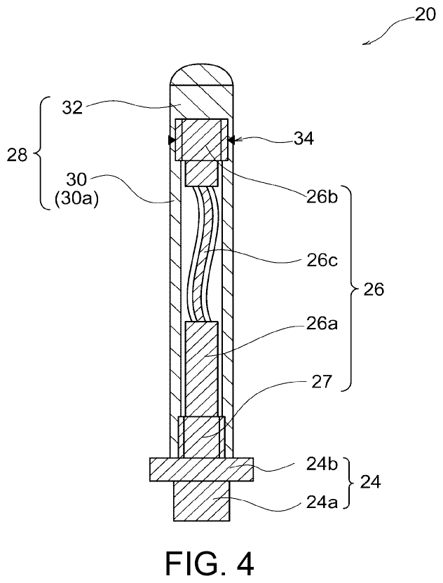

FIGS. 1 to 3 show an example of a ceramic susceptor 10, while FIG. 4 shows an example of an RF rod 20 included in the ceramic susceptor 10. The ceramic susceptor 10 includes a ceramic plate 12, a ceramic shaft 18, an RF rod 20, and a heater rod 22. An RF electrode 14 and a heater electrode 16 are embedded in the ceramic plate 12. The ceramic plate 12 is disk-shaped and has a first surface 12a for a wafer (not shown) being placed, and a second surface 12b opposite the first surface 12a. A cylindrical ceramic shaft 18 is attached to the second surface 12b of the ceramic plate 12. The ceramic shaft 18 is cylindrical and has an internal space S. The RF rod 20 is provided such that one end of the RF rod 20 is directly or indirectly connected to the RF electrode 14, and the other end of the RF rod 20 extends from the second surface 12b and extends through the internal space S. The heater rod 22 is provided such that one end of the heater rod 22 is directly or indirectly connected to the heater electrode 16, and the other end of the heater rod 22 extends from the second surface 12b and extends through the internal space S. The RF rod 20 has a root portion 24, a core portion 26, and an outer circumferential portion 28. The root portion 24 includes an end portion that fits into a terminal hole 12c formed in the second surface 12b of the ceramic plate 12. The core portion 26 extends from the root portion 24 in a direction away from the second surface 12b. The outer circumferential portion 28 is made of a non-magnetic material and is provided so as to cover the outer circumference of the core portion 26. In this way, the RF rod 20 is employed that includes the root portion 24 and the core portion 26 as well as the outer circumferential portion 28, made of a non-magnetic material, that covers the outer circumference of the core portion 26. This makes it possible to provide a ceramic susceptor 10 that can desirably achieve low impedance of the RF rod for preventing increase in heat generation accompanying higher frequencies.

In other words, as mentioned above, the RF current has also increased in recent years as the RF power required for plasma CVD has increased. In addition, due to the skin effect which becomes more pronounced as the frequency increases, the impedance of the RF rod continues to increase. Furthermore, the applied plasma power has been increasing in recent years, and the RF rod generates heat due to the RF current, causing worsening of the process results and deterioration of the connection parts (melting, burning, degeneration, etc.) to grow apparent. Therefore, it is conceivable to reduce the impedance of the RF rod in order to reduce the heat generation due to the RF current. However, employing an existing configuration for achieving low impedance of the RF rod generates various disadvantages. For example, Patent Literature 1 (JP7129587B) says that a W/Ni hybrid rod utilizing a non-magnetic material and Curie temperature achieves low impedance of the RF rod. However, the low impedance characteristics causes the temperature of the nickel portion not to rise quickly at the beginning of the process. It thus takes a long time for the nickel portion to reach the Curie temperature and stabilize the process, resulting in a new problem in which it takes a long time to obtain target characteristics. In addition, the tungsten portion is oxidized with long-term use, and the process results disadvantageously changes over time (so-called aging). Furthermore, the weight of the W/Ni hybrid rod is large (about three times that of a conventional rod). Since stress applied in the lateral direction (i.e., in a direction substantially perpendicular to the rod axis) also increases the moment generated at the brazed joint portion in proportion to the weight ratio, a problem sometimes has been caused in which the brazed joint portion may be broken by transportation or handling. On the other hand, Patent Literature 2 (JP6586259B) discloses Au plating on Ni rods as described above. However, it is difficult to plate the entire rod after brazing. In addition, if Au plating is applied to the outer circumferential surface of the rod before brazing, there also has been a problem in which the Au plating melts off in the brazing process of the rod with the ceramic heater. One or more of these various disadvantages are eliminated by the ceramic susceptor 10 of the present invention (especially the RF rod 20 having a unique configuration). In particular, the outer circumferential portion 28 of the RF rod 20, through which the RF current flows in a concentrated manner due to the skin effect, is composed of a non-magnetic material, and is made into a separate component from the core portion 26 and root portion 24 that respectively compose the interior and bottom of the RF rod 20, making it possible to prevent increase in resistance when the RF current flows in a concentrated manner through the outer circumferential portion 28. In other words, unlike ferromagnetic materials, non-magnetic materials have properties in which the resistance is less likely to increase if a large amount of RF current flows. Therefore, selectively employing a non-magnetic material for the outer circumferential portion 28 makes it possible to achieve low impedance and prevent increase in heat generation accompanying higher frequencies. At the same time, the role of support for the RF rod 20 can be ensured by the core portion 26 and root portion 24.

In the ceramic plate 12, the main portion (i.e., ceramic base) other than the embedded members such as the RF electrode 14 and the heater electrode 16 preferably contains aluminum nitride or aluminum oxide, and more preferably contains aluminum nitride, in terms of excellent thermal conductivity, high electrical insulation, and thermal expansion characteristics close to those of silicon.

The ceramic plate 12 is disk-shaped. However, a shape of the disk-shaped ceramic plate 12 in a plan view does not need to be a perfect circle. The shape may be, for example, an incomplete circle with a missing part such as an orientation flat. The size of the ceramic plate 12 may be appropriately determined according to the diameter of the wafer to be used, but is not particularly limited. In the case of a circle, the diameter is typically 150 to 450 mm, and particularly for 300 mm silicon wafers, the diameter is typically 320 to 380 mm. The thickness of the ceramic plate 12 is typically 10 to 25 mm.

The second surface 12b of the ceramic plate 12 is provided with terminal holes 12c for enabling terminal connection to each of the RF electrode 14 and the heater electrode 16, and is configured such that the RF rod 20 and the heater rod 22 can be inserted into the RF electrode 14 and the heater electrode 16, respectively. The second surface 12b of the ceramic plate 12 may also be provided with a thermocouple hole 12d for inserting a thermocouple (not shown).

The ceramic shaft 18 is a cylindrical member with an internal space S, and may be configured similarly to a ceramic shaft employed in a known ceramic susceptor or ceramic heater. The internal space S is configured such that terminal rods such as the RF rod 20 and the heater rod 22 pass therethrough. The ceramic shaft 18 is preferably made of the same ceramic material as the ceramic plate 12. The ceramic shaft 18 therefore preferably contains aluminum nitride or aluminum oxide, and more preferably contains aluminum nitride. The upper end surface of the ceramic shaft 18 is preferably joined to the second surface 12b of the ceramic plate 12 by solid phase joining or diffusion joining. The outer diameter of the ceramic shaft 18 is not particularly limited, but is preferably 40 to 60 mm. The inner diameter of the ceramic shaft 18 (diameter of the internal space S) is also not particularly limited, but is preferably 33 to 55 mm.

The heater electrode 16 is not particularly limited, but may be, for example, a conductive coil wired with a single stroke across the entire surface of the ceramic plate 12. The heater rod 22 is connected directly or indirectly (for example, via a connection member 17) to both ends of the heater electrode 16 for power supply. The heater rod 22 extends through the internal space S and is connected to a heater power source (not shown). When power is supplied from the heater power source, the heater electrode 16 generates heat to heat the wafer placed on the surface of the ceramic plate 12. The heater electrode 16 is not limited to a coil, and may be, for example, a ribbon (an elongated, thin plate), a mesh, or a print.

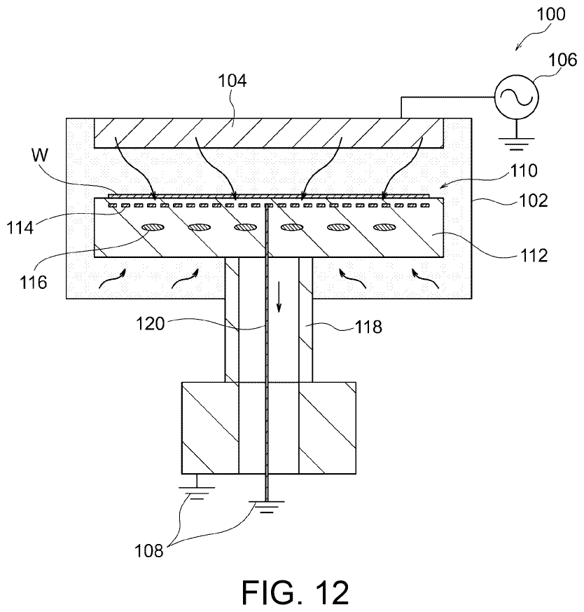

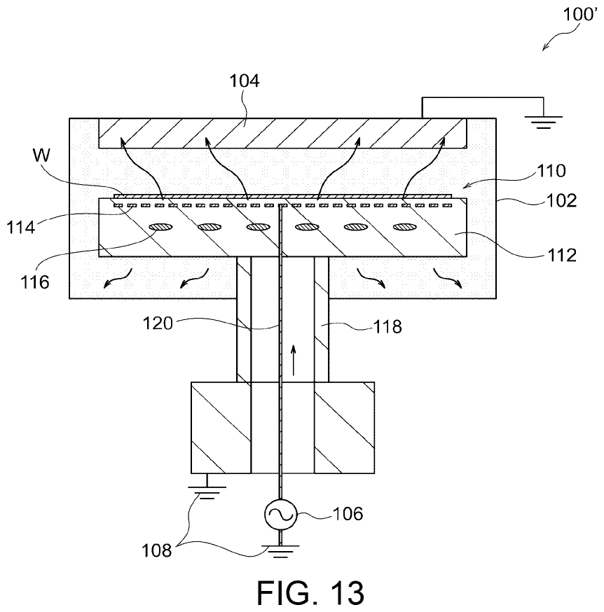

The RF electrode 14 is an electrode to which high frequency waves is applied to enable film deposition through a plasma CVD process. The RF electrode 14 is preferably a circular thin-layer electrode with a diameter slightly smaller than that of the ceramic plate 12, and may be, for example, a mesh electrode made by weaving thin metal wires into a net shape to make a sheet shape. The RF electrode 14 is connected to the RF rod 20 directly or indirectly (for example, via a connection member 15) for power supply. The RF rod 20 extends through the internal space S, and is connected to an external power source (see RF power source 106 in FIG. 13) or is grounded (see ground 108 in FIG. 12).

The RF electrode 14 may also function as an ESC electrode. ESC electrode is an abbreviation for electrostatic chuck (ESC) electrode, and is also called an electrostatic electrode. If the RF electrode 14 functions as an ESC electrode, the RF electrode 14 (or the ESC electrode) chucks a wafer placed on the surface of the ceramic plate 12 by the Johnsen-Rahbek force when a voltage is applied by an external power source.

The RF rod 20 has the root portion 24, the core portion 26, and the outer circumferential portion 28, and is rod-shaped as a whole.

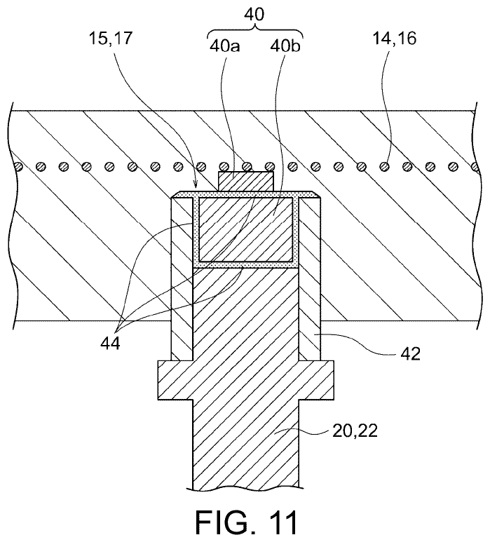

The root portion 24 includes an end portion 24a that is fitted into a terminal hole 12c formed in the second surface 12b of the ceramic plate 12. Therefore, the end portion 24a has a shape that is insertable into the terminal hole 12c (or an eyelet 42, described later with reference to FIG. 11). In addition, the root portion 24 preferably has a flange 24b adjacent to the end portion 24a. The flange 24b is a portion that applies a force to press the RF rod 20 (particularly the end portion 24a) toward the ceramic plate 12 when the RF rod 20 is inserted into the terminal hole 12c, and may also serve to restrict and position the end portion of the outer circumferential portion 28.

The core portion 26 extends from the root portion 24 in a direction away from the second surface 12b. The core portion 26 preferably includes a rod-shaped member, a cable-shaped member, or a combination thereof. The core portion 26, together with the root portion 24, serves as a support for the RF rod 20. In addition, the end portion of the core portion 26 adjacent to the root portion 24 preferably expands in diameter to form an engagement portion 27 that can be fitted or screwed into the cylindrical portion 30, thereby allowing the outer circumferential portion 28 to be fixed. Alternatively, the end portion of the core portion 26 adjacent to the root portion 24 may be provided with an engagement portion 27 that can be fitted or screwed into cylindrical portion 30 as a different member (from the core portion 26 and the root portion 24), thereby allowing the outer circumferential portion 28 to be fixed. Therefore, the engagement portion 27 may be part of the core portion 26, or may be a different member from the core portion 26. In any case, the engagement portion 27 preferably has a diameter equal to the inner diameter of the cylindrical portion 30.

The core portion 26 and the root portion 24 preferably contain nickel or titanium, and are more preferably made of nickel or titanium. The core portion 26 and the root portion 24, which are made of nickel or titanium, can maintain low electrical resistance. Therefore, they are suitable for use as portions through which DC current (for use in wafer chucking by electrostatic chuck) flows. In addition, the core portion 26 and the root portion 24 are preferably made of the same kind of metal material.

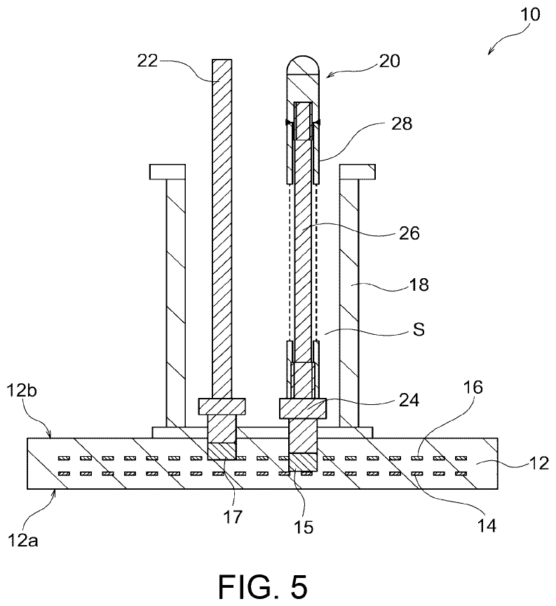

According to a preferred aspect of the present invention, as shown in FIG. 4, the core portion 26 may include a first rod-shaped member 26a composing the portion of the core portion 26 on the root portion 24 side, a second rod-shaped member 26b composing the head end portion of the core portion 26 on the opposite side of the root portion 24, and a cable-shaped member 26c interposed between the first rod-shaped member 26a and the second rod-shaped member 26b. In this aspect, the cable-shaped member 26c can absorb the difference in thermal expansion coefficient between: the non-magnetic material (e.g., brass) composing the outer circumferential portion 28; and the material (e.g., nickel) composing the core portion 26 and the root portion 24. In other words, the cable-shaped member 26c can bend due to its own flexibility, and can thereby absorb displacement caused by the difference in thermal expansion coefficient in use at high temperatures. Alternatively, according to another preferred aspect of the present invention, the core portion 26 may be composed of a single rod-shaped member 26a as shown in FIGS. 5, 6, and 10.

The outer circumferential portion 28 is a member that is made of a non-magnetic material and provided to cover the outer circumference of the core portion 26. As mentioned above, unlike ferromagnetic materials, non-magnetic materials have properties in which the resistance is less likely to increase if a large amount of RF current flows. Therefore, selectively employing a non-magnetic material for the outer circumferential portion 28 makes it possible to achieve low impedance and prevent increase in heat generation accompanying higher frequencies. The non-magnetic material composing the outer circumferential portion 28 preferably includes at least one selected from the group consisting of brass, titanium, stainless steel, chromium, tungsten, molybdenum, and gold. However, it is more preferable that the main portion of the outer circumferential portion 28 be made of the above non-magnetic material other than gold or chromium, and that the gold or chromium be applied to the surface of the outer circumferential portion 28 in the form of plating. In other words, the surface of the outer circumferential portion 28 is preferably plated with gold and/or chromium. Gold plating is particularly preferable because it also functions as an anti-oxidation film for the non-magnetic material composing the outer circumferential portion 28. In addition, chromium plating also functions as a gold diffusion prevention layer as a base for gold plating, and is therefore preferably used in combination with gold plating.

The outer circumferential portion 28 preferably includes the cylindrical portion 30 and a cap portion 32 that closes the end portion of the cylindrical portion 30 on the opposite side of the root portion 24. The cylindrical portion 30 is preferably composed of a tubular member and/or a mesh member shaped into a cylindrical shape. Alternatively, the cylindrical portion 30 may be a metal foil rolled into a cylindrical shape. In any case, the cylindrical portion 30 and the cap portion 32 are preferably plated with gold and/or chromium, as described above.

The outer circumferential portion 28 can be attached to the core portion 26, for example, as follows. First, the rod composed of the core portion 26 and the root portion 24 is brazed to the RF electrode 14 and/or the connection member 15. Then, the outer circumferential portion 28 (i.e., the cylindrical portion 30 and the cap portion 32), which has been plated with gold or the like in advance, is attached to the core portion 26 or the engagement portion 27 by a known method such as screwing or spot welding so as to cover the outer circumference of the core portion 26.

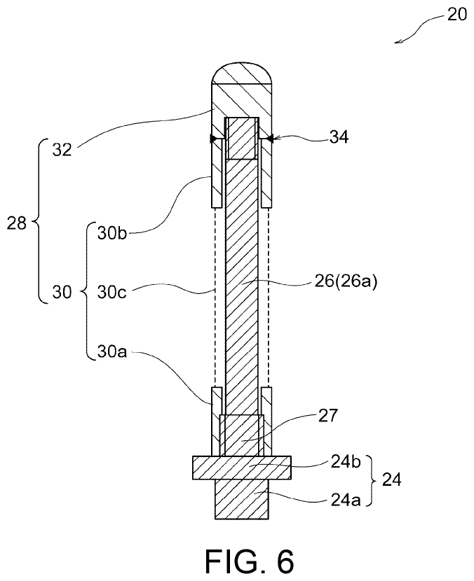

According to a preferred aspect of the present invention, as shown in FIGS. 5 and 6, the cylindrical portion 30 may include a first tubular member 30a composing the portion of the cylindrical portion 30 on the side of the root portion 24, a second tubular member 30b composing the head end portion of the cylindrical portion 30 on the opposite side of the root portion 24, and a mesh member 30c interposed between the first tubular member 30a and the second tubular member 30b. In this aspect, the mesh member 30c can absorb the difference in thermal expansion coefficient between: the non-magnetic material (e.g., titanium) composing the cylindrical portion 30; and the material (e.g., nickel) composing the cylindrical portion 30 and the root portion 24. In other words, the mesh member 30c can bend due to its own flexibility, and can thereby absorb displacement caused by the difference in thermal expansion coefficient in use at high temperatures. The first tubular member 30a, the second tubular member 30b, and the mesh member 30c are components of the cylindrical portion 30. Therefore, they are preferably made of a non-magnetic material, which is the same as the constituent material of the cylindrical portion 30 described above, and their surfaces are preferably plated with gold and/or chromium. A preferred example of the mesh member 30c is a mesh made of titanium, tungsten, or molybdenum, the surface of which is gold-plated. Alternatively, according to another preferred aspect of the present invention, the cylindrical portion 30 may be composed of a single tubular member 30a as shown in FIGS. 1 to 4 and 10. A preferred example of this single tubular member 30a is a tubular member made of brass or titanium, the surface of which is gold-plated.

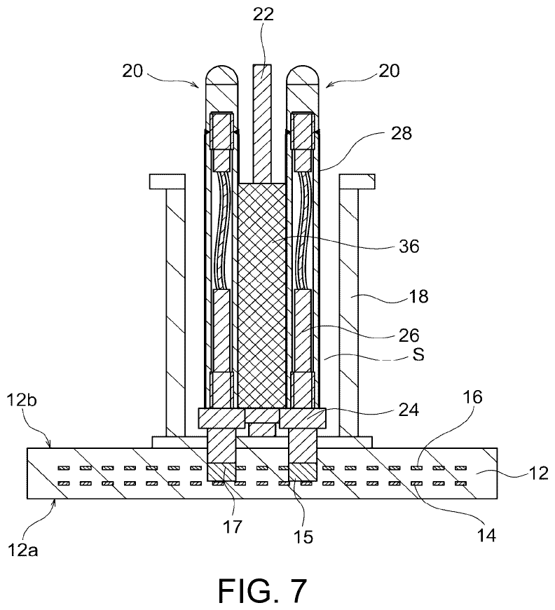

As shown in FIGS. 7 to 9, the ceramic susceptor 10 may include a plurality of RF rods 20. In this case, the plurality of RF rods 20 are preferably connected in the internal space S by a connecting member 36 made of a non-magnetic material in at least one form selected from the group consisting of mesh, foil, and plate. If the form is mesh, foil, or plate, any of them can connect the RF rods 20 by a non-magnetic material in a form having a planar spread. This makes it possible to further reduce the impedance of the RF rods 20. The non-magnetic material composing the connecting member 36 preferably contains at least one selected from the group consisting of brass, titanium, stainless steel, chromium, tungsten, and molybdenum.

The heater rod 22 may have the same configuration as a heater rod employed in a known ceramic susceptor or ceramic heater. Therefore, the heater rod 22 may be made of the same material (e.g., nickel or titanium) as the core portion 26 and the root portion 24 of the RF rod 20, and is not particularly limited.

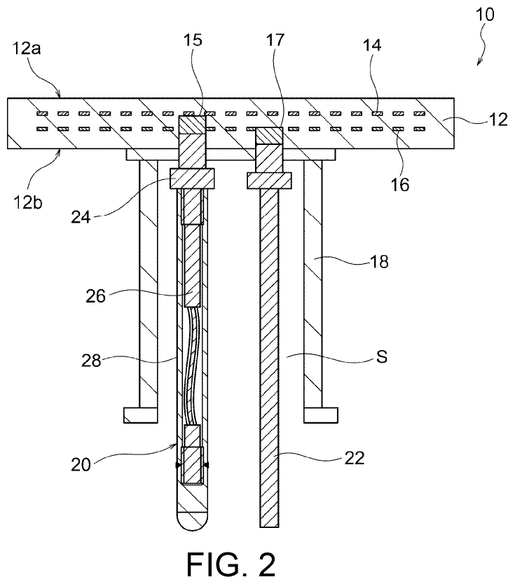

As described above, the RF rod 20 is connected directly or indirectly to the RF electrode 14, while the heater rod 22 is connected directly or indirectly to the heater electrode 16. The RF rod 20 and the heater rod 22 may be directly joined to the RF electrode 14 and the heater electrode 16, respectively, by brazing or the like. Alternatively, the RF rod 20 and the heater rod 22 may be respectively brazed to the RF electrode 14 and the heater electrode 16 via connection members 15 and 17 including a metal member such as Mo, as shown in FIGS. 2, 3, 5, and 7. The connection members 15 and 17 are not particularly limited, and may have a known connection structure including a metal member such as Mo.

A preferred example of the connection members 15 and 17 is shown in FIG. 11. The connection members 15 and 17 shown in FIG. 11 include a metal member 40 and an eyelet 42.

The metal member 40 is a member that interposes between the RF rod 20 and the RF electrode 14 and/or between the heater rod 22 and the heater electrode 16, to assists in ensuring the electrical connection between them. The configuration of the metal member 40 is not particularly limited. Preferably, the metal member 40 includes a tablet 40a and/or a buffer material 40b, and more preferably, the metal member 40 includes both the tablet 40a and the buffer material 40b. The tablet 40a is a block-shaped metal member (for example, formed in a mesh shape) that makes it easier to ensure electrical connection between the RF rod 20 and the RF electrode 14, and is provided on the RF electrode 14 side. Similarly, the tablet 40a can also be provided on the heater electrode 16 side to ensure electrical connection between the heater rod 22 and the heater electrode 16. This ensures a sufficient contact area for brazing the RF rod 20, the heater rod 22, and/or the buffer material 40b. Preferred examples of the metal composing the tablet 40a include Mo, W, and a W—Mo alloy, and Mo is preferred. The buffer material 40b is a metal member provided as a buffer to reduce the thermal expansion difference between the tablet 40a and the RF rod 20 and/or the thermal expansion difference between the tablet 40a and the heater rod 22. The buffer material 40b is provided between the tablet 40a and the RF rod 20 and/or between the tablet 40a and the heater rod 22. Preferred examples of the metal composing the buffer material 40b include alloys such as Kovar® (Fe—Ni—Co alloy). When the metal member 40 includes the tablet 40a and the buffer material 40b, it is preferable to braze the RF rod 20, the buffer material 40b, and the tablet 40a to each other using a brazing material 44 (e.g., Au). Similarly, it is preferable to braze the heater rod 22, the buffer material 40b, and the tablet 40a to each other using a brazing material 44 (e.g., Au).

The eyelet 42 is a cylindrical member that is made of a metal and is fitted into the terminal hole 12c. The eyelet 42 serves to guide smooth insertion of the RF rod 20 or the heater rod 22 into the terminal hole 12c. The eyelet 42 may be threaded. In this case, the RF rod 20 or the heater rod 22 may also be threaded, so that the RF rod 20 or the heater rod 22 can be inserted while being screwed into the eyelet 42. The metal composing the eyelet 42 is not particularly limited, but preferred examples include Ni, W, Mo, and W—Mo alloys, and Ni is preferred. The eyelet 42 may also have a male thread on its outer circumference. Providing a threaded portion allows the terminal hole 12c and the eyelet 42 to be screwed together.

Below, various embodiments employing various RF rods 20 will be described with reference to the drawings.

### First Embodiment

The first embodiment is an aspect that employs an RF rod 20 in which: a gold-plated brass tube is used for the outer circumferential portion 28; and a cable-shaped member, made of nickel, is used for the core portion 26. This embodiment corresponds to the configuration of the ceramic susceptor 10 and the RF rod 20 shown in FIGS. 1 to 4. Accordingly, in the first embodiment, the core portion 26 includes the first rod-shaped member 26a, the second rod-shaped member 26b, and the cable-shaped member 26c interposed between them, as described above. Furthermore, as described above, the outer circumferential portion 28 includes a cylindrical portion 30 and a cap portion 32, and the cylindrical portion 30 is composed of a single tubular member 30a. Hereinafter, in this embodiment, the member in which the root portion 24, the first rod-shaped member 26a, the cable-shaped member 26c, and the second rod-shaped member 26b are connected in this order will be referred to as a “Ni cable rod”. The specifications of the RF rod 20 in the first embodiment are as follows.

### <Ni Cable Rod>

Root portion 24: A member, made of nickel, with an end portion 24a and a flange 24b
First rod-shaped member 26a: A nickel rod (having an engagement portion 27 expanded in diameter at its end portion)
Second rod-shaped member 26b: Nickel rod
Cable-shaped member 26c: Nickel cable

### <Outer Circumferential Portion 28>

Cylindrical portion 30: A brass tube with gold-plated outer surface (thickness of gold plating: about 10 μm)
Cap portion 32: A cap portion, made of brass, with gold-plated outer surface (thickness of gold plating: about 10 μm), having a cap shape that closes one end of the cylindrical portion 30.
   *Stainless steel (SUS 316) may be used instead of brass for the cylindrical portion 30 and cap portion 32.

The RF rod 20 in the first embodiment can be attached to the ceramic plate 12 as follows. First, the root portion 24 (particularly the end portion 24a) of the Ni cable rod is inserted into the terminal hole 12c of the ceramic plate 12, and the root portion 24 is brazed to the RF electrode 14 via the connection member 15. The joining temperature at this time is about 1000° C. If gold plating is present at this time, the gold will melt in brazing and the plating will detach, so the Ni cable rod cannot be gold-plated in advance. Next, the cylindrical portion 30, which is a gold-plated brass tube, is arranged so as to accommodate the Ni cable rod inside. The end portion of the cylindrical portion 30 is then screwed into the engagement portion 27 of the Ni cable rod. At this time, the end portion of the cylindrical portion 30 is restricted by the flange 24b, and is thereby positioned. The gold-plated brass tube, which is the cylindrical portion 30 arranged in this way, is welded to the gold-plated cap portion 32 made of brass at the joint portion 34. This makes it possible to prevent the cap portion 32 from loosening and coming off from the cylindrical portion 30, and to ensure sufficient electrical connection. In this way, an RF rod 20 is obtained that has a structure in which the core portion 26 of the Ni cable rod is covered with the outer circumferential portion 28 (the cylindrical portion 30 and the cap portion 32). Although brass and nickel have different thermal expansion coefficients, the cable-shaped member 26c (nickel cable) can absorb the difference in thermal expansion coefficient between: the brass composing the outer circumferential portion 28; and the nickel composing the core portion 26 and the root portion 24. For example, a displacement of about 1 mm occurs due to a thermal expansion difference between brass and nickel over a length of 300 mm. But this embodiment can effectively absorb such a difference in thermal expansion coefficient and displacement. In addition, in this embodiment, the outer surface of the outer circumferential portion 28 (i.e., the cylindrical portion 30 and the cap portion 32) is gold-plated, and the technical significance thereof is explained as follows. First, if nickel is gold-plated, the gold diffuses and forms an Au—Ni alloy, so gold plating to a Ni tube and a Ni cable rod should be avoided (i.e., a gold-plated Ni tube cannot be used). In addition, nickel is a ferromagnetic material, so it cannot be used for the outer circumferential portion 28 through which high frequency waves flow. In terms of this point in this embodiment, gold-plating is applied to the outer surface of the outer circumferential portion 28 (the cylindrical portion 30 and the cap portion 32) made of brass. This preferably achieves anti-oxidation of the brass composing the base of the gold plating and reduction of impedance by the paramagnetic material, at operating temperatures up to about 700° C.

### Second Embodiment

The second embodiment is an aspect that employs an RF rod 20 in which: a gold-plated titanium tube is used for the outer circumferential portion 28; and a cable-shaped member, made of nickel, is used for the core portion 26. This embodiment also corresponds to the configuration of the ceramic susceptor 10 and the RF rod 20 shown in FIGS. 1 to 4, and has the same configuration as the first embodiment, except that titanium is used instead of brass for the outer circumferential portion 28 as described below.

### <Outer Circumferential Portion 28>

Cylindrical portion 30: A titanium tube with the gold-plated outer surface (the thickness of gold plating: about 10 μm)
Cap portion 32: A cap portion, made of titanium, with gold-plated outer surface (thickness of gold plating: about 10 μm), having a cap shape that closes one end of the cylindrical portion 30.
   *Stainless steel (SUS 316) may be used instead of titanium for the cylindrical portion 30 and cap portion 32.

The RF rod 20 in the second embodiment can also be attached to the ceramic plate 12 in the same manner as in the first embodiment, except that titanium is used instead of brass. Although titanium and nickel have different thermal expansion coefficients, the cable-shaped member 26c (nickel cable) can absorb the difference in thermal expansion coefficient between: the titanium composing the outer circumferential portion 28; and the nickel composing the core portion 26 and root portion 24. For example, a displacement of about 0.8 mm occurs due to a thermal expansion difference between titanium and nickel over a length of 300 mm. But this embodiment can effectively absorb such a difference in thermal expansion coefficient and displacement. In addition, in this embodiment, the outer surface of the outer circumferential portion 28 (i.e., the cylindrical portion 30 and the cap portion 32) is gold-plated, and the technical significance thereof is explained as follows. First, if nickel is gold-plated, the gold diffuses and forms an Au—Ni alloy, so gold plating to a Ni tube and a Ni cable rod should be avoided (i.e., a gold-plated Ni tube cannot be used). In addition, nickel is a ferromagnetic material, so it cannot be used for the outer circumferential portion 28 through which high frequency waves flow. In terms of this point in this embodiment, gold-plating is applied to the outer surface of the outer circumferential portion 28 (the cylindrical portion 30 and the cap portion 32) made of titanium. This preferably achieves anti-oxidation of the titanium composing the base of the gold plating and reduction of impedance by the paramagnetic material, at operating temperatures up to about 700° C.

### Third Embodiment

The third embodiment is an aspect that employs an RF rod 20 in which: a gold-plated mesh member, made of titanium, is used for the outer circumferential portion 28; and a rod-shaped member made of nickel (not including a cable-shaped member) is used for the core portion 26. This embodiment corresponds to a configuration of the ceramic susceptor 10 and RF rod 20 shown in FIGS. 5 and 6. Therefore, in the third embodiment, the core portion 26 includes a single rod-shaped member 26a. As described above, the outer circumferential portion 28 includes the cylindrical portion 30 and the cap portion 32, The cylindrical portion 30 is composed of a first tubular member 30a, a second tubular member 30b, and a mesh member 30c interposed between them. Hereinafter, the integral body composed of the root portion 24 and the rod-shaped member 26a in this embodiment will be referred to as a “Ni rod”. The specifications of the RF rod 20 in the third embodiment are as follows.

### <Ni Rod>

Root portion 24: A member, made of nickel, with an end portion 24a and a flange 24b
Core portion 26 (rod-shaped member 26a): A nickel rod (having an engagement portion 27 expanded in diameter at its end portion)

### <Outer Circumferential Portion 28>

First tubular member 30a: A titanium tube with the gold-plated outer surface (the thickness of gold plating: about 10 μm)
Second tubular member 30b: A titanium tube with the gold-plated outer surface (the thickness of gold plating: about 10 μm)
Mesh member 30c: A mesh sleeve, made of titanium, tungsten or molybdenum, with the gold-plated outer surface (50 mesh (wire diameter: 0.12 mm and mesh size: about 0.4 mm) or 24 mesh (wire diameter: 0.35 mm and mesh size: about 0.7 mm)) (the thickness of gold plating: about 10 μm)
   (*For the mesh made of tungsten or molybdenum, chrome plating is provided between the mesh and gold plating. Also, for the mesh made of titanium, a TiN layer may be provided between the mesh and gold plating.)
Cap portion 32: A cap portion, made of titanium, with gold-plated outer surface (thickness of gold plating: about 10 μm), having a cap shape that closes one end of the cylindrical portion 30.

The RF rod 20 in the third embodiment can be attached to the ceramic plate 12 as follows. Note that the following description will be given for the case in which a mesh sleeve, made of titanium, with a gold-plated outer surface is used as the mesh member 30c, but the same applies to the case in which a gold-plated mesh sleeve, made of tungsten or molybdenum, is used. First, the root portion 24 (particularly the end portion 24a) of the Ni rod is inserted into the terminal hole 12c of the ceramic plate 12, and the root portion 24 is brazed to the RF electrode 14 via the connection member 15. The joining temperature at this time is about 1000° C. If gold plating is present at this time, the gold will melt in brazing and the plating will detach, so the Ni rod cannot be gold-plated in advance. Then, the cylindrical portion 30, which is a gold-plated tube/mesh sleeve composite made of titanium, is arranged so as to accommodate the Ni rod inside. The end portion of the cylindrical portion 30 is then screwed into the engagement portion 27 of the Ni rod. At this time, the end portion of the cylindrical portion 30 is restricted by the flange 24b, and is thereby positioned. The cylindrical portion 30 (particularly the gold-plated titanium tube) arranged in this way is welded to the gold-plated cap portion 32 made of titanium at the joint portion 34. This makes it possible to prevent the cap portion 32 from loosening and coming off from the cylindrical portion 30, and to ensure sufficient electrical connection. In this way, an RF rod 20 is obtained that has a structure in which the core portion 26 of the Ni rod is covered with the outer circumferential portion 28 (the cylindrical portion 30 and the cap portion 32). Although titanium and nickel have different thermal expansion coefficients, the mesh member 30c (mesh sleeve made of titanium) can absorb the difference in thermal expansion coefficient between: the titanium composing the outer circumferential portion 28; and the nickel composing the core portion 26 and the root portion 24. The mesh member 30c can absorb displacement of about ±1 mm without any problems. In addition, in this embodiment, the outer surface of the outer circumferential portion 28 (i.e., the cylindrical portion 30 and the cap portion 32) is gold-plated, and the technical significance thereof is explained as follows. First, if nickel is gold-plated, the gold diffuses and forms an Au—Ni alloy, so gold plating to a Ni tube and a Ni cable rod should be avoided (i.e., a gold-plated Ni tube cannot be used). In addition, nickel is a ferromagnetic material, so it cannot be used for the outer circumferential portion 28 through which high frequency waves flow. However, titanium is a paramagnetic material and is suitable for the outer circumferential portion 28 through which high frequency waves flow. However, titanium is an active material and quickly oxidizes and deteriorates in high temperature range. In terms of this point in this embodiment, gold-plating is applied to the outer surface of the outer circumferential portion 28 (the cylindrical portion 30 and the cap portion 32) made of titanium. This preferably achieves anti-oxidation of the titanium composing the base of the gold plating and reduction of impedance by the paramagnetic material, at operating temperatures up to about 700° C.

### Fourth Embodiment

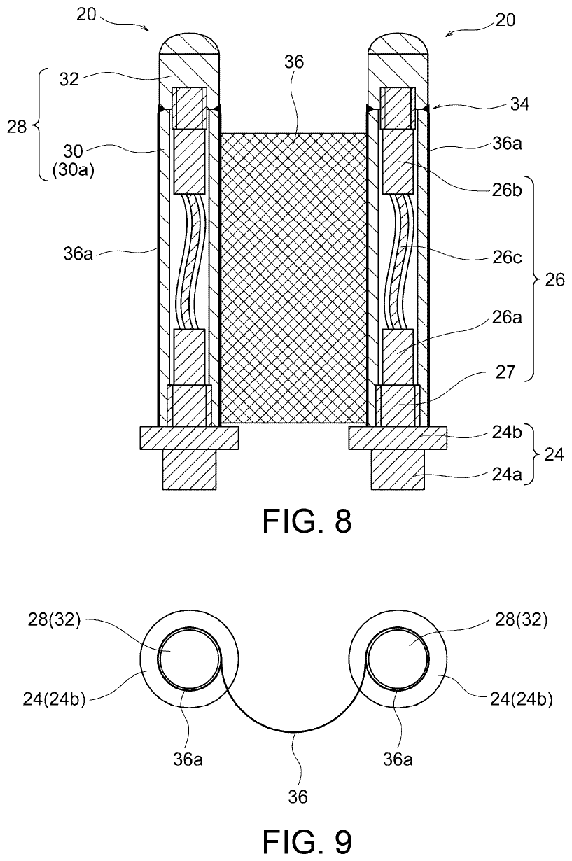

The fourth embodiment is an aspect in which a plurality of RF rods 20 are connected as shown in FIGS. 7 to 9. In other words, as described above, the plurality of RF rods 20 are connected by a connecting member 36 made of a non-magnetic material. This makes it possible to further reduce the impedance of the RF rods 20. In this embodiment, two RF rods 20 are connected by a thin plate or mesh connecting member 36 made of titanium, brass or stainless steel (SUS 316) with a gold-plated surface. As shown in FIGS. 7 to 9, the connecting member 36 is provided so as to bridge the cylindrical portions 30 of the opposite RF rods 29. Each portion of the connecting member 36, which wraps around and is fixed to a cylindrical portion 30, is shaped into a thin-walled pipe 36a having a thickness of 1 mm or less. The thin-walled pipe 36a is not limited to being formed to wrap around the cylindrical portion 30 of the connecting member 36, but may be formed in advance into a cylindrical shape into which the cylindrical portion 30 can be inserted. The connecting member 36 is preferably provided over the substantially entire area in the length direction of each cylindrical portion 30, as shown in FIG. 8, from the viewpoint of reducing impedance. However, the connecting member 36 may be provided only on part in the length direction of the cylindrical portion 30. In addition, the connecting member 36 is preferably configured to be provided so as to reach the joint portion 34 between the cylindrical portion 30 and the cap portion 32 so that the connecting member 36 can be welded and fixed at the same time when the joint portion 34 is welded.

In FIGS. 7 to 9, employed RF rods 20 have a similar configuration to that of the first or second embodiment, but the RF rod 20 is not limited to this, and it is also possible to employ the RF rod 20 of the third embodiment. Therefore, the attachment of the plurality of RF rods 20 to the ceramic plate 12 can be performed in the same manner as in the first, second, or third embodiment, except that the connecting member 36 is provided. The connecting member 36 is welded at the same time when the joint portion 34 is welded, and thereby the connecting member 36 is fixed to the RF rods 20.

### Fifth Embodiment

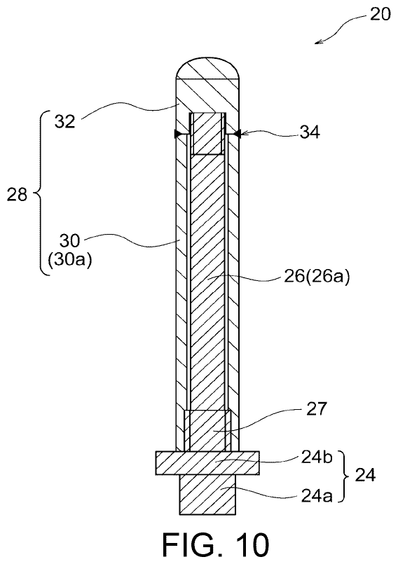

The fifth embodiment is an aspect that employs an RF rod 20 in which: a gold-plated titanium tube is used for the outer circumferential portion 28; and a rod-shaped member made of titanium (not including a cable-shaped member) is used for the core portion 26. As shown in FIG. 10, the RF rod 20 according to the fifth embodiment employs the outer circumferential portion 28 in the second embodiment, and corresponds to a configuration in which the Ni rod in the third embodiment is replaced with a Ti rod. Therefore, as described above, the core portion 26 includes a single rod-shaped member 26a. Furthermore, as described above, the outer circumferential portion 28 includes a cylindrical portion 30 and a cap portion 32, and the cylindrical portion 30 is composed of a single tubular member 30a. In other words, in the fifth embodiment, there is no need for members that absorb thermal expansion differences, such as the cable-shaped member 26c or mesh member 30c. This is because not only the outer circumferential portion 28 but also the root portion 24 and the core portion 26 are made of titanium, creating no difference in thermal expansion coefficient. The specifications of the RF rod 20 in the fifth embodiment are as follows.

### <Ti Rod>

Root portion 24: A member, made of titanium, with an end portion 24a and a flange 24b
Core portion 26 (rod-shaped member 26a): A titanium rod (having an engagement portion 27 expanded in diameter at its end portion)

### <Outer Circumferential Portion 28>

Cylindrical portion 30: A titanium tube with the gold-plated outer surface (the thickness of gold plating: about 10 μm)
Cap portion 32: A cap portion, made of titanium, with gold-plated outer surface (thickness of gold plating: about 10 μm), having a cap shape that closes one end of the cylindrical portion 30.

The RF rod 20 in the fifth embodiment can be attached to the ceramic plate 12 as follows. First, the root portion 24 of the Ti rod is inserted into the terminal hole 12c of the ceramic plate 12, and the root portion 24 (particularly the end portion 24a) is brazed to the RF electrode 14 via the connection member 15. The joining temperature at this time is about 1000° C. If gold plating is present at this time, the gold will melt in brazing and the plating will detach, so the Ti rod cannot be gold-plated in advance. Next, the cylindrical portion 30, which is a gold-plated titanium tube, is arranged so as to accommodate the Ti rod inside. The end portion of the cylindrical portion 30 is then screwed into the engagement portion 27 of the Ti rod. At this time, the end portion of the cylindrical portion 30 is restricted by the flange 24b, and is thereby positioned. The gold-plated titanium tube, which is the cylindrical portion 30 arranged in this way, is welded to the gold-plated cap portion 32 made of titanium at the joint portion 34. This makes it possible to prevent the cap portion 32 from loosening and coming off from the cylindrical portion 30, and to ensure sufficient electrical connection. In this way, the RF rod 20 is obtained that has a structure in which the core portion 26 of the Ti rod is covered with the outer circumferential portion 28 (the cylindrical portion 30 and the cap portion 32). In addition, in this embodiment, the outer surface of the outer circumferential portion 28 (i.e., the cylindrical portion 30 and the cap portion 32) is gold-plated, and the technical significance thereof is explained as follows. First, titanium is a paramagnetic material and is suitable for the outer circumferential portion 28 through which high frequency waves flow. However, titanium is an active material and quickly oxidizes and deteriorates in high temperature range. In terms of this point in this embodiment, gold-plating is applied to the outer surface of the outer circumferential portion 28 (the cylindrical portion 30 and the cap portion 32) made of titanium. This preferably achieves anti-oxidation of the titanium composing the base of the gold plating and reduction of impedance by the paramagnetic material, at operating temperatures up to about 700° C.

What is claimed is:

1. A ceramic susceptor comprising:
a disk-shaped ceramic plate having a first surface and a second surface, the ceramic plate having an RF electrode and a heater electrode embedded in the ceramic plate;
a cylindrical ceramic shaft attached to the second surface of the ceramic plate, the ceramic shaft having an internal space;
an RF rod having one end connected directly or indirectly to the RF electrode, the RF rod having another end extending from the second surface and extending through the internal space; and
a heater rod having one end connected directly or indirectly to the heater electrode, the heater rod having another end extending from the second surface and extending through the internal space,
wherein the RF rod includes:
a root portion including an end portion to be fitted into a terminal hole formed in the second surface of the ceramic plate;
a core portion extending from the root portion in a direction away from the second surface; and
an outer circumferential portion entirely covering an outer circumference of the core portion, the outer circumferential portion being made of a non-magnetic material comprising at least one selected from the group consisting of brass, titanium, stainless steel, chromium, tungsten, molybdenum, and gold.

2. The ceramic susceptor according to claim 1, wherein a surface of the outer circumferential portion is plated with gold and/or chromium.

3. The ceramic susceptor according to claim 1, wherein the outer circumferential portion includes:
a cylindrical portion composed of a tubular member and/or a mesh member formed into a cylindrical shape; and
a cap portion that closes an end portion of the cylindrical portion, the end portion being on an opposite side of the root portion.

4. The ceramic susceptor according to claim 1, wherein the core portion and the root portion comprises nickel or titanium.

5. The ceramic susceptor according to claim 1, wherein the core portion includes a rod-shaped member, a cable-shaped member, or a combination thereof.

6. The ceramic susceptor according to claim 1, wherein the core portion includes:
a first rod-shaped member composing a portion of the core portion on a side of the root portion;
a second rod-shaped member composing a head end portion of the core portion on an opposite side of the root portion; and
a cable-shaped member interposed between the first rod-shaped member and the second rod-shaped member.

7. The ceramic susceptor according to claim 1, wherein the core portion is composed of a single rod-shaped member.

8. The ceramic susceptor according to claim 1, wherein the ceramic susceptor includes a plurality of the RF rods; and the plurality of the RF rods are connected in the internal space by a connecting member made of a non-magnetic material in at least one form selected from the group consisting of a mesh, a foil, and a plate.

9. The ceramic susceptor according to claim 8, wherein the non-magnetic material composing the connecting member contains at least one selected from the group consisting of brass, titanium, stainless steel, chromium, tungsten, and molybdenum.

10. The ceramic susceptor according to claim 1, wherein the RF electrode also functions as an ESC electrode.
